(19) United States
(12) Patent Application Publication
(10) Pub. No.: US 2006/0275950 A1
(43) Pub. Date: Dec. 7, 2006

(54) Method of manufacturing a flexible display device

(76) Inventor: Woo-Jae Lee, Yongin-si (KR)

Correspondence Address: CANTOR COLBURN, LLP, 55 GRIFFIN ROAD SOUTH, BLOOMFIELD, CT, 06002, US

(21) Appl. No.: 11/362,403

(22) Filed: Feb. 24, 2006

(30) Foreign Application Priority Data
Jun. 1, 2005 (KR) 10-2005-0046641

(51) Int. Cl. H01L 21/00

(52) U.S. Cl. 438/107; 156/249; 156/247; 438/149; 349/187; 29/825; 29/831

(57) ABSTRACT

A method of manufacturing a flexible display includes the steps of coating an adhesive on a first surface of a flexible substrate or a supporter, adhering the first surface of the flexible substrate to the supporter using the adhesive, and forming a thin film pattern on a second surface of the flexible substrate. The flexible substrate and the supporter are prevented from bending during the manufacturing process even when the flexible substrate is large.

### CROSS REFERENCE TO RELATED APPLICATION

This application claims priority to and the benefit of Korean Patent Application No. 10-2005-0046641, filed on Jun. 1, 2005, which is hereby incorporated by reference for all purposes as if fully set forth herein.

### BACKGROUND OF THE INVENTION

1. Field of the Invention

The present invention relates to a method of manufacturing a flexible display device. The display device includes a flexible substrate.

2. Discussion of the Background

The most widely used flat panel displays are liquid crystal displays (LCD) and organic light emitting displays (OLED).

An LCD includes two panels with a liquid crystal (LC) layer interposed between them. The panels may be provided with polarizers and field-generating electrodes, such as pixel electrodes and common electrodes. An LCD displays images by applying voltages to the field-generating electrodes to generate an electric field in the LC layer. The electric field changes the orientation of the LC molecules in the LC layer to adjust the polarization of incident light.

An organic light emitting diode (OLED) display is a self emissive display device that displays images by exciting an emissive organic material to emit light. The OLED includes an anode, also known as a hole injection electrode, a cathode, also known as an electron injection electrode, and an organic light emission layer interposed between the two electrodes. The holes and the electrons are injected into the light emission layer where they are recombined. The recombination annihilates both the hole and the electron and emits light as a byproduct.

Liquid crystal displays and organic light emitting displays that include a fragile and heavy glass substrate are not adequately portable or suitable for use in large displays.

To overcome the problems associated with glass substrates, a display device using a plastic substrate has been developed. Plastic is advantageous as a substrate because it is light, strong, and flexible. But it is difficult to form thin film patterns such as electrodes and signal lines on a plastic substrate because the substrate bends and expands when heated.

Attempts have been made to solve this problem by attaching a plastic substrate to a glass supporter, forming thin film patterns on the plastic substrate, and removing the plastic substrate from the glass supporter. Conventional methods of adhering a plastic substrate to a glass supporter include using a middle film with adhesives formed on both surfaces of the middle film. But, because the adhesives and the middle film have different coefficients of thermal expansion from the plastic substrate and the glass supporter, the plastic substrate and the glass supporter are easily bent during the display device manufacturing process. This is especially true when the display is large. Therefore, a method is needed to manufacture a large display device with a flexible substrate that will not cause the substrate and glass supporter to bend during the manufacturing process.

### SUMMARY OF THE INVENTION

To solve these problems, this invention provides a method of manufacturing a flexible display device in which an adhesive is coated directly on either a flexible substrate or a glass supporter. The flexible substrate is then attached to the glass supporter, thin film patterns are formed on the flexible substrate, and the flexible substrate is removed from the glass supporter. The flexible substrate and the supporter are prevented from bending during the display device manufacturing process even when the flexible substrate is large.

Additional features of the invention will be set forth in the description which follows, and in part will be apparent from the description, or may be learned by practice of the invention.

The present invention discloses a method of manufacturing a flexible display device that includes coating a first surface of a flexible substrate or a first surface of a supporter with an adhesive, adhering the first surface of the flexible substrate to the first surface of the supporter using the adhesive, and forming a thin film pattern on a second surface of the flexible substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A, FIG. 1B, FIG. 1C, FIG. 1D, FIG. 1E, FIG. 1F, FIG. 1G, and FIG. 1H are sectional views illustrating a manufacturing method of a flexible display device according to an exemplary embodiment of the present invention.

FIG. 2 is a layout view of an LCD according to an exemplary embodiment of the present invention.

FIG. 3A and FIG. 3B are sectional views of the LCD shown in FIG. 2 taken along the lines IIIA-IIIA and IIIB-IIIB.

FIG. 4, FIG. 6, FIG. 8, and FIG. 10 are layout views of intermediate steps of a method of manufacturing the TFT array panel shown in FIG. 2, FIG. 3A, and FIG. 3B.

FIG. 5a and FIG. 5b are sectional views of the TFT array panel shown in FIG. 4 taken along the lines VA-VA and VB-VB.

FIG. 7A and FIG. 7B are sectional views of the TFT array panel shown in FIG. 6 taken along the lines VIIA-VIIA and VIIB-VIIB.

FIG. 9A and FIG. 9B are sectional views of the TFT array panel shown in FIG. 8 taken along the lines IXA-IXA and IXB-IXB.

FIG. 11A and FIG. 11B are sectional views of the TFT array panel shown in FIG. 10 taken along the lines XIA-XIA and XIB-XIB.

FIG. 12A, FIG. 12B, FIG. 12C, and FIG. 12D are sectional views of intermediate steps of a method to manufacture a common electrode panel according to an exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

It will be understood that when an element such as a layer, film, region or substrate is referred to as being “on” another element, it can be directly on the other element or intervening elements may also be present. In contrast, when an element is referred to as being “directly on” another element, there are no intervening elements present.

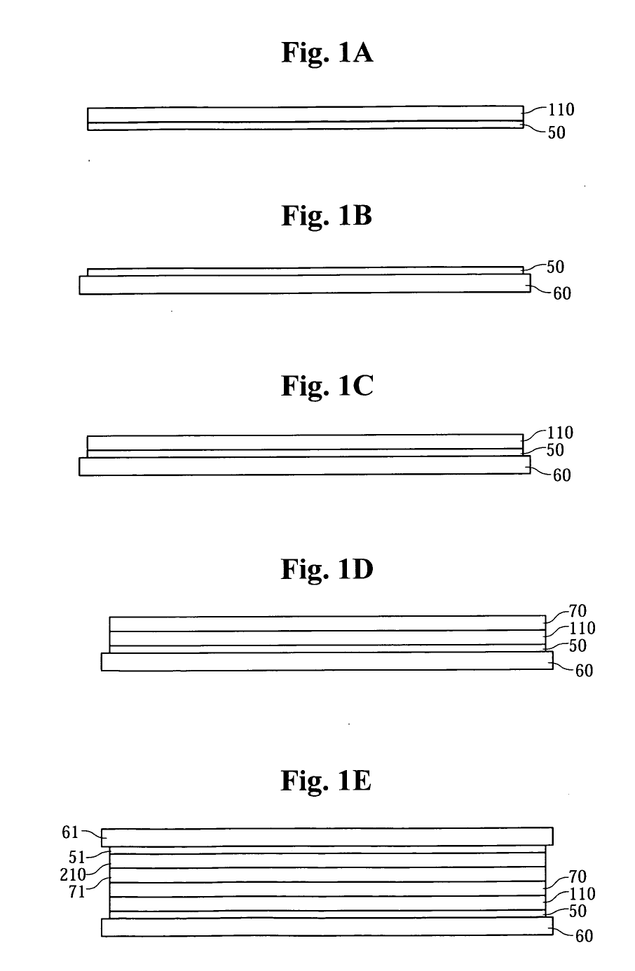

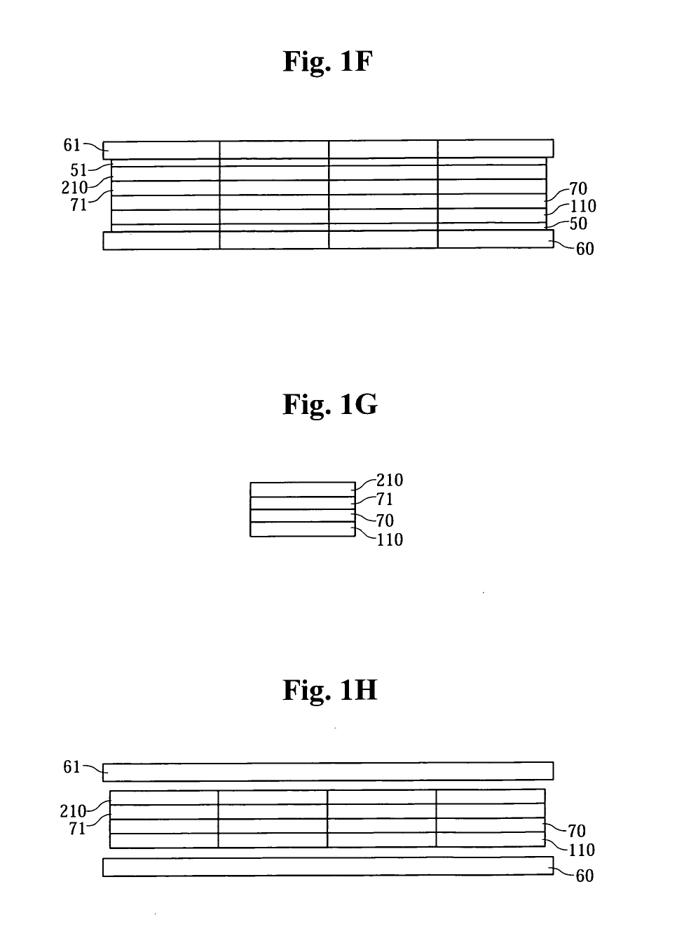

A method of manufacturing a flexible display device according to an exemplary embodiment of the present invention will now be described in detail with reference to FIG. 1A, FIG. 1B, FIG. 1C, FIG. 1D, FIG. 1E, FIG. 1F, FIG. 1G, and FIG. 1H.

FIG. 1A, FIG. 1B, FIG. 1C, FIG. 1D, FIG. 1E, FIG. 1F, FIG. 1G, and FIG. 1H are sectional views illustrating a manufacturing method of a flexible display according to an exemplary embodiment of the present invention.

Referring to FIG. 1A and FIG. 1B, an adhesive 50 is coated directly on one surface of either a flexible substrate 110 or a supporter 60. The flexible substrate 110 and the supporter 60 are then adhered to each other as shown in FIG. 1C. Alternatively, both the flexible substrate 110 and the supporter 60 may be coated with the same or different adhesives.

The adhesive 50 may be in a liquefied state. The adhesive may be, but is not limited to, a temperature sensitive adhesive, an acrylic adhesive, or a silicone adhesive. The adhesive 50 may form a layer equal to or less than 10 μm thick to minimize stress due to thermal expansion.

The flexible substrate 110 may include an organic layer made of polyacrylate, polyethylene-ether-phthalate, polyethylene-naphthalate, polycarbonate, polyarylate, polyether-imide, polyethersulfone, or polyimides. The flexible substrate 110 may also include an under-coating layer (not shown) made of acrylic resin and a barrier layer (not shown) made of SiO₂ or Al₂O₃. The flexible substrate 110 may also include a hard-coating layer made of acrylic resin formed on both surfaces of the flexible substrate 10. These layers protect the flexible substrate 110 from physical and chemical damage.

The supporter 60 may be made of glass, but is not limited thereto. The size of the flexible substrate 110 may be equal to or less than the supporter 60.

The adhesive 50 layer coated directly on the flexible substrate 10 or the supporter 60 is thinner than previously known adhesion methods that include the use of an adhesive tape applied to both sides of a solid film. Also, unlike the solid film, the adhesive 50 layer does not undergo thermal expansion, which minimizes bending of the flexible substrate 10 and the supporter. The lack of bending makes the method of the present invention suitable to manufacture a large flexible substrate.

The present invention is more cost effective than conventional adhesive methods that included the use of adhesive tape applied to both sides of a solid film because conventional adhesive methods requires two layers of adhesive, while the present invention requires only one.

Referring to FIG. 1D, a thin film pattern 70 is formed on the flexible substrate 110 attached to the supporter 60. The flexible substrate 110 does not bend or expand because it is solidly adhered to the supporter 60.

Referring to FIG. 1E, the flexible substrate 10, the thin film pattern 70, and the supporter 60 are combined with another flexible substrate 210, a thin film pattern 71, and a supporter 61 by adhesive 51. A liquid crystal layer (not shown) may be formed by dripping liquid crystal material on one of the two flexible substrates 110 and 210 before combining them. If the display device is to be an OLED display, only one substrate need be used, and the thin film Pattern 71 will include an organic emitting layer.

Referring to FIG. 1F, the flexible substrates 110 and 210 including the thin film patterns 70 and 71 and the supporters 60 and 61 are divided into display device units of predetermined size.

Thereafter, the supporters 60 and 61 are removed from the flexible substrates 110 and 210 to complete a display device as shown in FIG. 1G.

As a substitute of the step of FIG. 1F, as shown in FIG. 1H, the supporters 60 and 61 may be removed from the flexible substrates 110 and 210 before the flexible substrates 110 and 210 and the thin film patterns 70 and 71 are divided into display device units. In this case, the supporters 60 and 61 may be reused.

The flexible substrates 110 and 210 may be included in a panel of a display device such as an LCD or an OLED.

The panel for an LCD will now be described in detail with reference to the drawings.

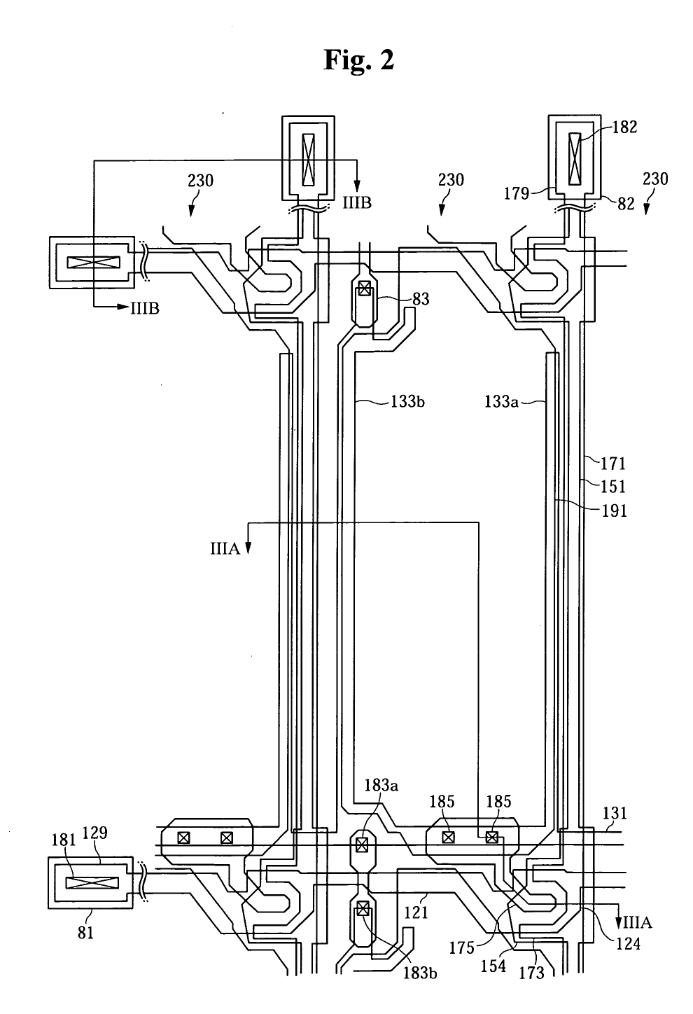

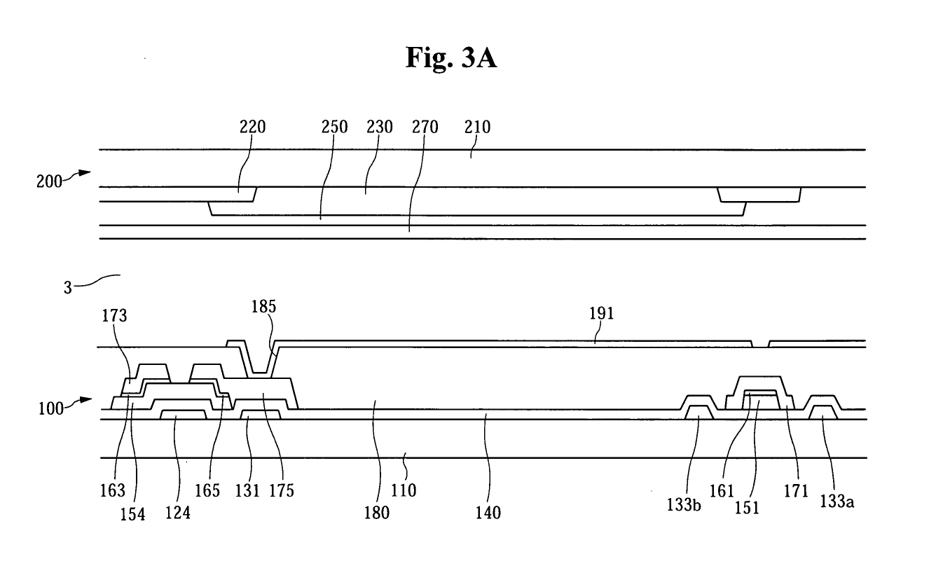

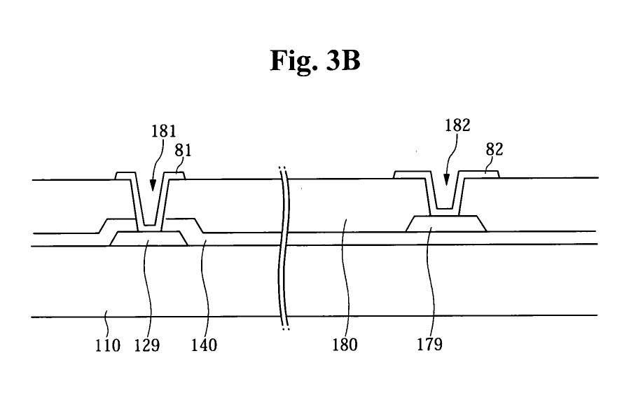

FIG. 2 is a layout view of an LCD according to an exemplary embodiment of the present invention, and FIG. 3A and FIG. 3B are sectional views of the LCD shown in FIG. 2 taken along the lines IIIa-IIIa and IIIb-IIIb.

An LCD according to an exemplary embodiment of the present invention includes a TFT array panel 100, a common electrode panel 200, and an LC layer 3 interposed between the panels 100 and 200.

The TFT array panel 100 will now be described in detail.

A plurality of gate lines 121 and a plurality of storage electrode lines 131 are formed on a flexible substrate 110.

The gate lines 121 transmit gate signals and extend in a substantially transverse direction. Each of the gate lines 121 includes a plurality of gate electrodes 124 projecting upward and an end portion 129 having a large area for contact with another layer or an external driving circuit. A gate driving circuit (not shown) for generating the gate signals may be mounted on a flexible printed circuit (FPC) film (not shown), which may be attached to the substrate 110, directly mounted on the substrate 110, or integrated onto the substrate 110. The gate lines 121 may extend to be connected to a driving circuit that may be integrated on the substrate 110.

The storage electrode lines 131 are supplied with a predetermined voltage. Each of the storage electrode lines 131 include a stem extending substantially parallel to the gate lines 121 and a plurality of pairs of storage electrodes 133a and 133b branched from the stem. Each of the storage electrode lines 131 is disposed between two adjacent gate lines 121. The stem is close to one of the two adjacent gate lines 121. Each of the storage electrodes 133a and 133b has a fixed end portion connected to the stem and a free end portion disposed opposite to the stem. The fixed end portion of the storage electrode 133b has a large area, and the free end portion is bifurcated into a linear branch and a curved branch. The storage electrode lines 131 may have other various shapes and arrangements.

The gate lines 121 and the storage electrode lines 131 may be made of an Al, an Al alloy, Ag, a Ag alloy, Cu, a Cu alloy, Mo, a Mo alloy, Cr, Ta, or Ti. The gate lines 121 may have a multi-layered structure including two conductive films (not shown) having different physical characteristics. One of the two films may be made of a low resistivity metal such as Al, an Al alloy, Ag, a Ag alloy, Cu, or a Cu alloy to reduce signal delay or voltage drop. The other film is preferably made of a material such as Mo, a Mo alloy, Cr, Ta, or Ti that has good physical, chemical, and electrical contact characteristics with other materials such as indium tin oxide (ITO) or indium zinc oxide (IZO). Examples of combinations of the two films are a lower Cr film with an upper Al alloy film, and a lower Al alloy film with an upper Mo alloy film. The gate lines 121 and the storage electrode lines 131 may be made of other various metals or conductors.

The lateral sides of the gate lines 121 and the storage electrode lines 131 are inclined relative to a surface of the substrate 110. The inclination angles may range between about 30 degrees to about 80 degrees.

A gate insulating layer 140 may be made of silicon nitride (SiNx) or silicon oxide (SiOx). The gate insulating layer 140 is formed on the gate lines 121 and the storage electrode lines 131.

A plurality of semiconductor stripes 151 may be made of hydrogenated amorphous silicon (abbreviated to “a-Si”), polysilicon, or an organic semiconductor. The semiconductor stripes 151 are formed on the gate insulating layer 140. Each of the semiconductor stripes 151 extends in a substantially longitudinal direction and includes a plurality of projections 154 branched out toward the gate electrodes 124. The semiconductor stripes 151 become wide near the gate lines 121 and the storage electrode lines 131 so that the semiconductor stripes 151 cover large areas of the gate lines 121 and the storage electrode lines 131.

A plurality of ohmic contact stripes 161 and islands 165 are formed on the semiconductor stripes 151. The ohmic contact stripes 161 and islands 165 may be made of n+ hydrogenated a-Si, heavily doped with an N-type impurity such as phosphorous, or may be made of silicide. Each ohmic contact stripe 161 includes a plurality of projections 163. The projections 163 and the ohmic contact islands 165 are located in pairs on the projections 154 of the semiconductor stripes 151.

The lateral sides of the semiconductor stripes 151 and the ohmic contacts 161 and 165 are inclined relative to a surface of the substrate 110. The inclination angles may range between about 30 degrees to about 80 degrees.

A plurality of data lines 171 and a plurality of drain electrodes 175 are formed on the ohmic contacts 161 and 165 and the gate insulating layer 140.

The data lines 171 transmit data signals and extend in a substantially longitudinal direction to intersect the gate lines 121 and the storage electrode lines 131. Each data line 171 intersects the storage electrode lines 131 and runs between adjacent pairs of storage electrodes 133a and 133b. Each data line 171 includes a plurality of source electrodes 173 projecting toward the gate electrodes 124, and an end portion 179 having a large area for contact with another layer or an external driving circuit. A data driving circuit (not shown) for generating the data signals may be mounted on an FPC film (not shown), which may be attached to the substrate 110, directly mounted on the substrate 110, or integrated onto the substrate 110. The data lines 171 may be connected to a driving circuit that may be integrated on the substrate 110.

The drain electrodes 175 are separated from the data lines 171 and are disposed opposite the source electrodes 173 on the other side of the gate electrodes 124. Each of the drain electrodes 175 includes a wide end portion and a narrow end portion. The wide end portion overlaps the storage electrode line 131 and the narrow end portion is partly enclosed by a source electrode 173.

A gate electrode 124, a source electrode 173, a drain electrode 175, and a projection 154 of a semiconductor stripe 151 form a TFT. The TFT has a channel formed in the projection 154 disposed between the source electrode 173 and the drain electrode 175. The TFT is an organic TFT when the semiconductor stripe 151 is made of an organic material.

The data lines 171 and the drain electrodes 175 may be made of a refractory metal such as Cr, Mo, Ta, Ti, or alloys thereof. The data lines 171 and the drain electrodes 175 may have a multilayered structure including a refractory metal film (not shown) and a low resistivity film (not shown). Examples of the multi-layered structure include a double-layered structure made of a lower Cr/Mo alloy film with an upper Al alloy film, and a triple-layered structure made of a lower Mo alloy film, an intermediate Al alloy film, and an upper Mo alloy film. The data lines 171 and the drain electrodes 175 may be made of other various metals or conductors.

The data lines 171 and the drain electrodes 175 are inclined relative to a surface of the substrate 110. The inclination angles may range between about 30 degrees to about 80 degrees.

The ohmic contacts 161 and 165 are interposed between the underlying semiconductor stripes 151 and the overlying conductors 171 and 175 to reduce the contact resistance between them. The semiconductor stripes 151 are narrower than the data lines 171 at most places, but the width of the semiconductor stripes 151 becomes larger near the gate lines 121 and the storage electrode lines 131 to smooth the profile of the surface and prevent disconnection of the data lines 171. The semiconductor stripes 151 include some exposed portions that are not covered by the data lines 171 and the drain electrodes 175, including portions located between the source electrodes 173 and the drain electrodes 175.

A passivation layer 180 is formed on the data lines 171, the drain electrodes 175, and the exposed portions of the semiconductor stripes 151.

The passivation layer 180 may be made of an inorganic or organic insulator, and may have a flat top surface. The inorganic insulator may be made of silicon nitride or silicon oxide. The organic insulator may be photosensitive and may have a dielectric constant of less than about 4.0. The passivation layer 180 may include a lower and upper film made of an inorganic insulator. The passivation layer 180 prevents the exposed portions of the semiconductor stripes 151 from being damaged.

The passivation layer 180 has a plurality of contact holes 182 and 185 exposing the end portions 179 of the data lines 171 and the drain electrodes 175, respectively. The passivation layer 180 and the gate insulating layer 140 have a plurality of contact holes 181 exposing the end portions 129 of the gate lines 121, a plurality of contact holes 183a exposing portions of the storage electrode lines 131 near the fixed end portions of the storage electrodes 133b, and a plurality of contact holes 183b exposing the linear branches of the free end portions of the storage electrodes 133b.

A plurality of pixel electrodes 191, a plurality of overpasses 83, and a plurality of contact assistants 81 and 82 are formed on the passivation layer 180.

The pixel electrodes 191 are physically and electrically connected to the drain electrodes 175 through the contact holes 185 so that the pixel electrodes 191 receive data voltages from the drain electrodes 175. The pixel electrodes 191 are supplied with data voltages to generate electric fields in cooperation with a common electrode (not shown) supplied with a common voltage. The common electrode is attached to the common electrode panel 200. The voltages determine the orientation of liquid crystal molecules (not shown) of a liquid crystal layer (not shown) disposed between the two electrodes. A pixel electrode 191 and the common electrode form a capacitor referred to as a “liquid crystal capacitor,” which stores applied voltages after the TFT turns off.

A pixel electrode 191 overlaps a storage electrode line 131 and the storage electrodes 133a and 133b. The pixel electrode 191, a drain electrode 175 connected to the pixel electrode, and the storage electrode line 131 form an additional capacitor referred to as a “storage capacitor,” which enhances the voltage storing capacity of the liquid crystal capacitor.

The contact assistants 81 and 82 are connected to the end portions 129 of the gate lines 121 and the end portions 179 of the data lines 171 through the contact holes 181 and 182, respectively. The contact assistants 81 and 82 protect the end portions 129 and 179 and enhance the adhesion between the end portions 129 and 179 and external devices.

The overpasses 83 cross over the gate lines 121 and are connected to the exposed portions of the storage electrode lines 131 and the exposed linear branches of the free end portions of the storage electrodes 133b through contact holes 183a and 183b, respectively, which are disposed opposite each other on either side of the gate lines 121. The storage electrode lines 131, the storage electrodes 133a and 133b, and the overpasses 83 can be used for repairing defects in the gate lines 121, the data lines 171, or the TFTs.

The common electrode panel 200 is now described in detail.

A black matrix 220 for preventing light leakage between pluralities of pixels is formed on a flexible substrate 210. The flexible substrate may be made of plastic. The light blocking member 220 may include a plurality of openings that face the pixels.

A plurality of color filters 230 are formed on the flexible substrate 210 and are substantially disposed in the areas enclosed by the light blocking member 220. The color filters 230 may extend along the pixel column in a substantially longitudinal direction to form stripes. The color filters 230 may display a primary color, for example, red, green, or blue.

An overcoat 250 is formed on the color filters 230 and the light blocking member 220 to prevent the color filters 230 from being exposed and to provide a flat surface.

A common electrode 270 is formed on the overcoat 250. The common electrode may be made of a transparent conductive material such as ITO or IZO.

Alignment layers (not shown) are formed on the inner surfaces of the two panels 100 and 200. At least one polarizer is provided on the outer surface of the two panels 100 and 200.

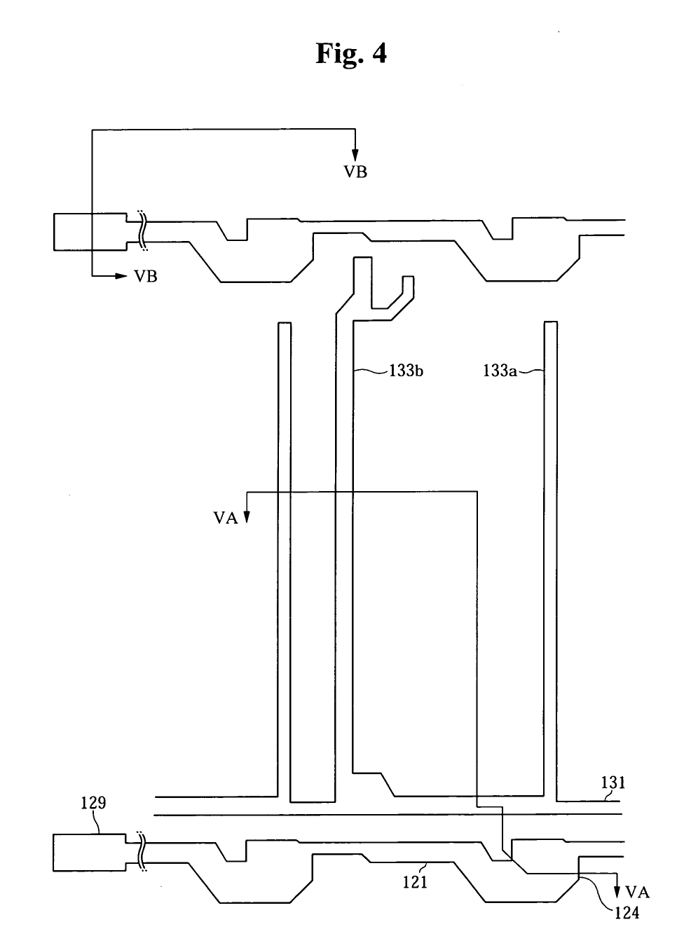

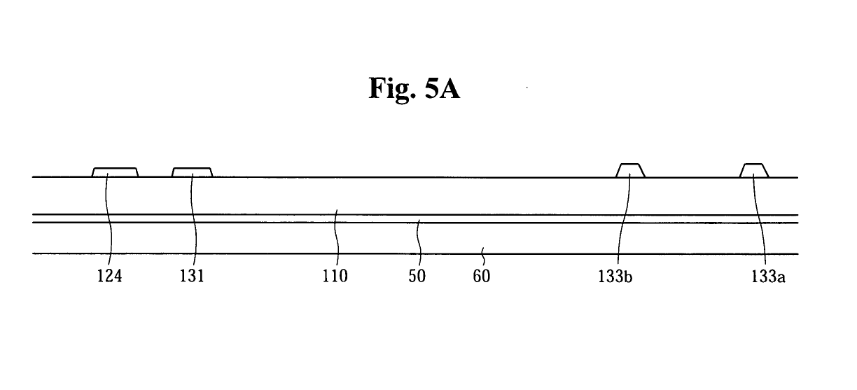

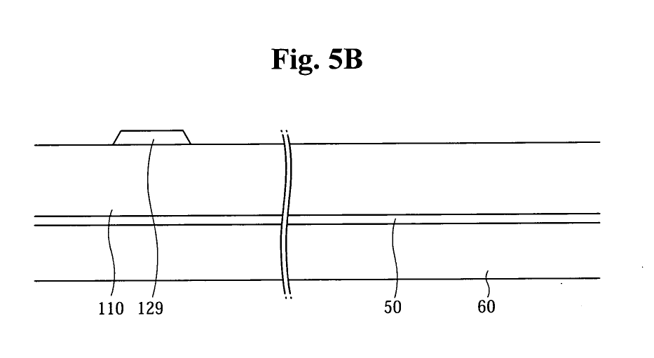

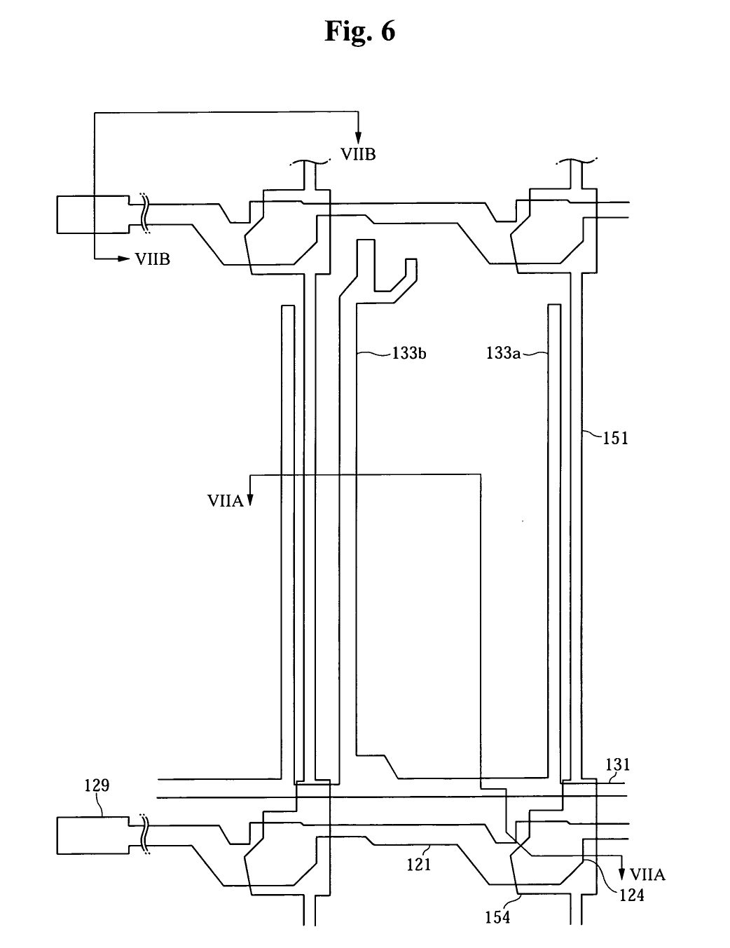

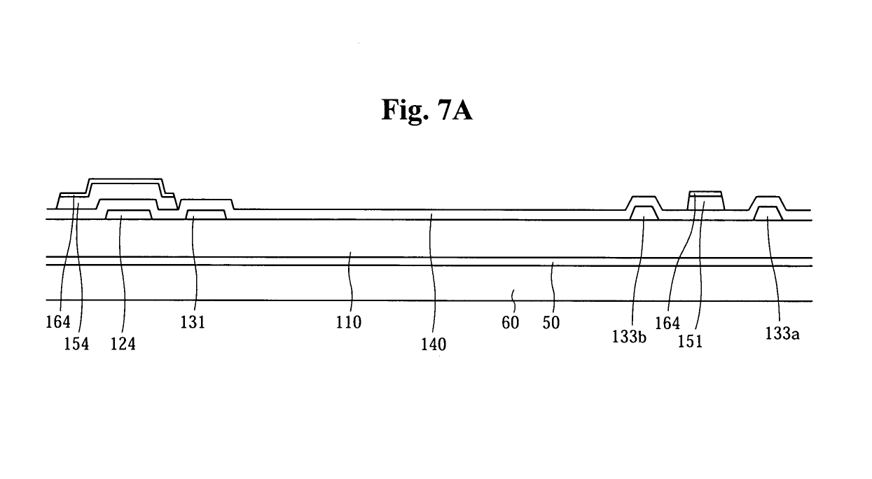

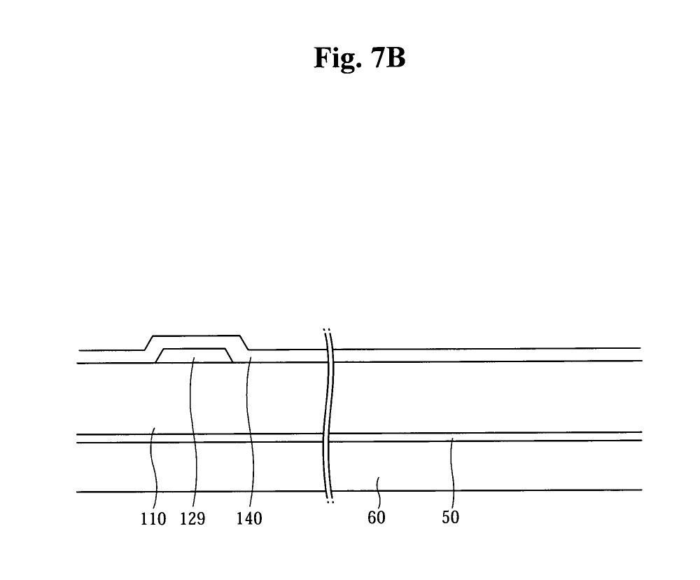

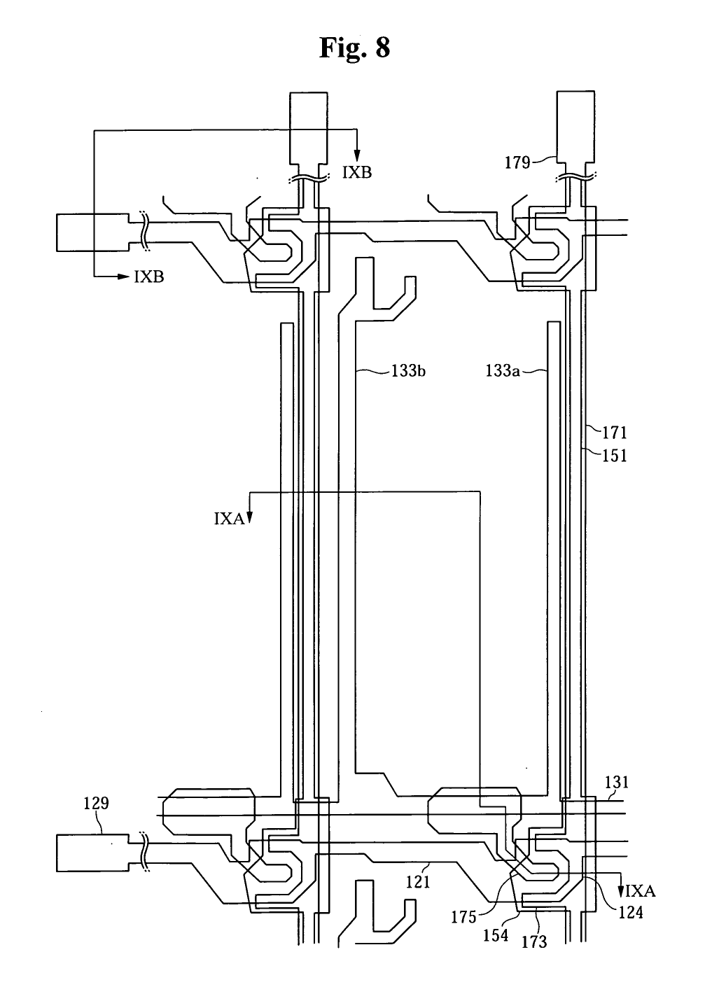

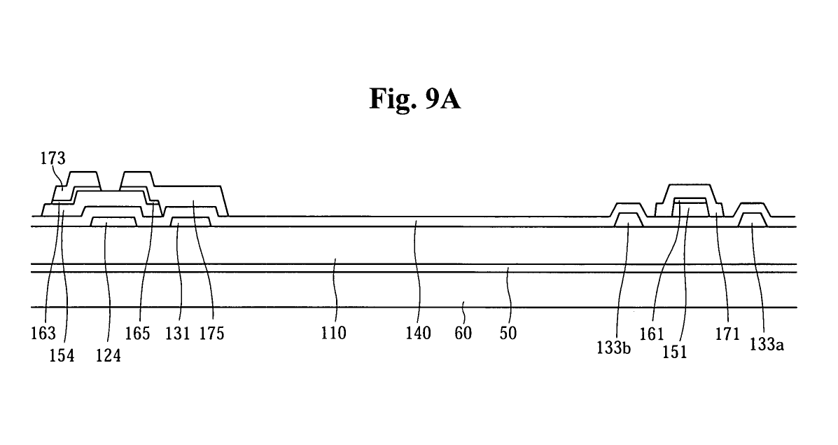

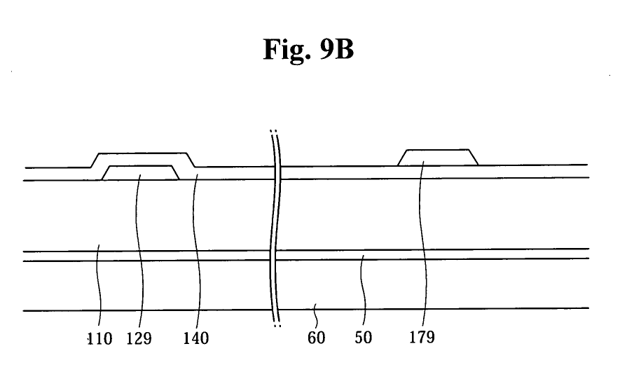

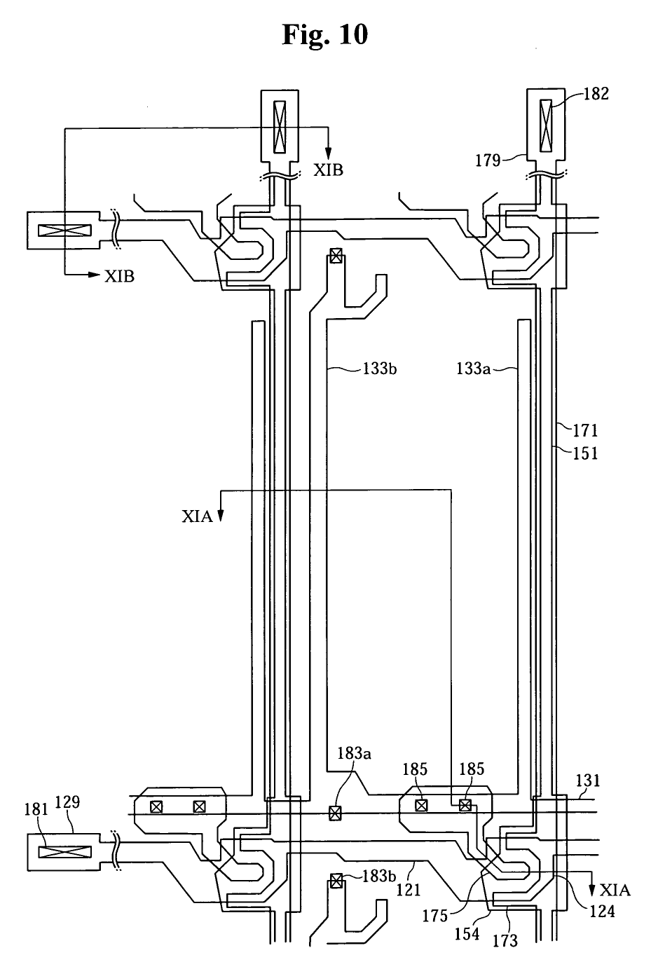

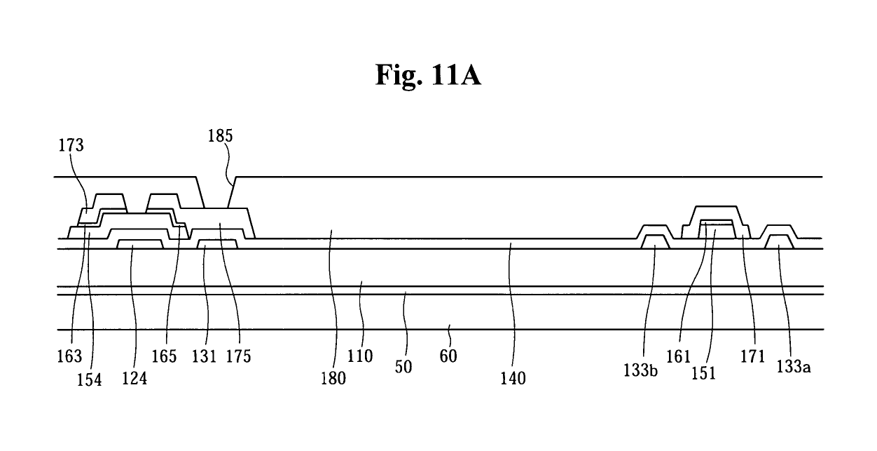

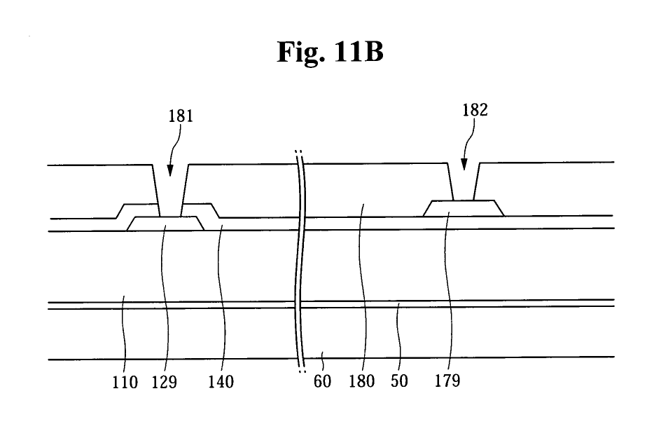

A method of manufacturing the TFT array panel 100 shown in FIG. 2, FIG. 3A, and FIG. 3B according to an exemplary embodiment of the present invention will be described in detail with reference to FIG. 2, FIG. 3A, FIG. 3B, FIG. 4, FIG. 5A, FIG. 5B, FIG. 6, FIG. 7A, FIG. 7B, FIG. 8, FIG. 9A, FIG. 9B, FIG. 10, FIG. 11A, and FIG. 11B.

FIG. 4, FIG. 6, FIG. 8, and FIG. 10 are layout views of intermediate steps of an exemplary manufacturing method used to make the TFT array panel shown in FIG. 2, FIG. 3A, and FIG. 3B. FIG. 5A and FIG. 5B are sectional views of the TFT array panel shown in FIG. 4 taken along the lines VA-VA and VB-VB. FIG. 7A and FIG. 7B are sectional views of the TFT array panel shown in FIG. 6 taken along the lines VIIA-VIIA and VIIB-VIIB. FIG. 9A and FIG. 9B are sectional views of the TFT array panel shown in FIG. 8 taken along the lines IXA-IXA and IXB-IXB. FIG. 11A and FIG. 11B are sectional views of the TFT array panel shown in FIG. 10 taken along the lines XIA-XIA and XIB-XIB.

As shown in FIG. 4, FIG. 5A, and FIG. 5B, an adhesive 50 is coated on a supporter 60. Next, a flexible substrate 110 is adhered to the supporter 60. Then a metal film is sputtered and patterned by photo-etching with a photoresist pattern on the flexible substrate 110 to form a plurality of gate lines 121, gate electrodes 124, end portions 129, storage electrode lines 131, and storage electrodes 133a and 133b.

Referring to FIG. 6, FIG. 7A, and FIG. 7B, a gate insulating layer 140, an intrinsic a-Si layer, and an extrinsic a-Si layer are sequentially deposited. The extrinsic a-Si layer and the intrinsic a-Si layer are photo-etched to form a plurality of extrinsic semiconductor stripes 164 and a plurality of intrinsic semiconductor stripes 151 including a plurality of projections 154 on the gate insulating layer 140.

Referring to FIG. 8, FIG. 9A, and FIG. 9B, a metal film is sputtered and etched using a photoresist to form a plurality of data lines 171 including a plurality of source electrodes 173, end portions 179, and drain electrodes 175.

Before or after removing the photoresist, portions of the extrinsic semiconductor stripes 164 not covered by the data lines 171 or the drain electrodes 175 are removed by etching to expose portions of the intrinsic semiconductor stripes 151 and also to form a plurality of ohmic contact stripes 161 including a plurality of projections 163 and ohmic contact islands 165. After etching, the exposed surfaces of the semiconductor stripes 151 may undergo an oxygen plasma treatment to stabilize the exposed surfaces of the semiconductor stripes 151.

Referring to FIG. 10, FIG. 11A, and FIG. 11B, a passivation layer 180 may be formed by either plasma enhanced chemical vapor deposition (PECVD) of an inorganic material or coating with a photosensitive organic material. The passivation layer 180 and the gate insulating layer 140 are then etched to form a plurality of contact holes 181, 182, 183a, 183b, and 185.

Referring to FIG. 2, FIG. 3A, and FIG. 3B, a conductive layer is deposited by sputtering. The conductive layer is preferably made of a transparent material such as ITO, IZO, or a-ITO (amorphous indium tin oxide). The conductive layer is etched using the photoresist to form a plurality of pixel electrodes 190 and a plurality of contact assistants 81 and 82. An alignment layer may also be formed.

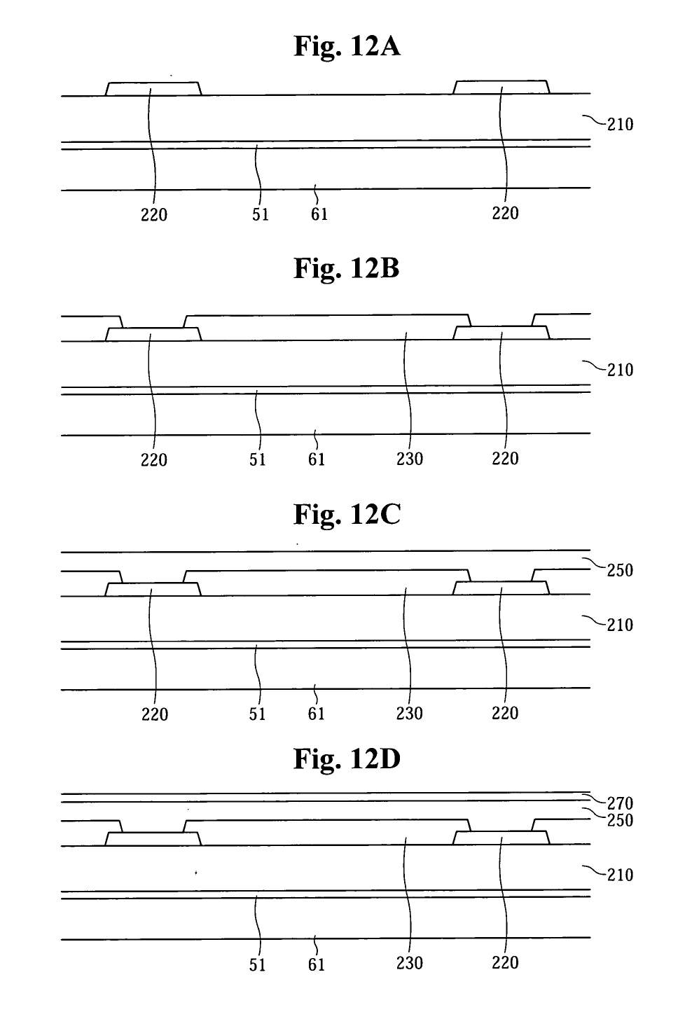

A method of manufacturing the common electrode panel 200 shown in FIG. 2, FIG. 3A, and FIG. 3B according to an exemplary embodiment of the present invention will now be described in detail with reference to FIG. 2, FIG. 3A, FIG. 3B, FIG. 12A, FIG. 12B, FIG. 12C, and FIG. 12D.

Referring to FIG. 12A, an adhesive 51 is coated on a supporter 61, and a flexible substrate 210 is adhered to the supporter 61. Next, a metal film with good characteristics for blocking light is sputtered on the flexible substrate 210 and then patterned by photo-etching with a photoresist pattern to form a light blocking member 220.

Referring to FIG. 12B, photosensitive compositions are coated on the flexible substrate 210 and then patterned by photo-etching to form a plurality of color filters 230. The color filters may display a primary color, for example, red, green, or blue.

Referring to FIG. 12C and FIG. 12D, an overcoat 250 is formed on the color filters 230 and the light blocking member 220. A common electrode 270 is formed on the overcoat 250. The common electrode 270 may be made of a transparent conductive material.

Next, the thin film transistor array panel 100 and the common electrode panel 200 are connected, and liquid crystal material is injected between the two panels 100 and 200. Alternatively, a liquid crystal layer (not shown) may be formed by dripping liquid crystal material on one of the two panels 100 and 200 before combining them.

The two panels 100 and 200 and the supporters 60 and 61 are divided into display device units of predetermined size. The adhesion power of the adhesive 50 and 51 may be neutralized using various methods including temperature control, solvents, or ultraviolet rays. The supporters 60 and 61 are then removed from the panels 100 and 200.

Alternatively, the supporters 60 and 61 may be removed from the two panels 100 and 200 before dividing the two panels 100 and 200 into display device units of predetermined size.

In the method depicted by FIG. 1A, FIG. 1B, FIG. 1C, FIG. 1D, FIG. 1E, FIG. 1F, FIG. 1G, and FIG. 1H, the thin film pattern 70 may include organic thin film transistors including organic semiconductors.

The method depicted by FIG. 1A, FIG. 1B, FIG. 1C, FIG. 1D, FIG. 1E, FIG. 1F, FIG. 1G, and FIG. 1H as described above may be adapted to other flat panel display devices, including but not limited to, a panel for an OLED.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method for manufacturing a flexible display device, comprising:
coating a first surface of a flexible substrate or a first surface of a supporter with an adhesive;
adhering the first surface of the flexible substrate to the first surface of the supporter using the adhesive; and
forming a thin film pattern on a second surface of the flexible substrate.

2. The method of claim 1,
wherein the adhesive is applied as a liquid.

3. The method of claim 1,
wherein the flexible substrate is made of plastic.

4. The method of claim 1,
wherein the size of the flexible substrate is equal to or smaller than the size of the supporter.

5. The method of claim 1,
wherein the adhesive forms a layer that is equal to or less than about 10 μm thick.

6. The method of claim 1,
wherein the adhesive is selected from the group of temperature sensitive adhesives, acrylic adhesives, and silicone adhesives.

7. The method of claim 1,
wherein the flexible substrate is coated by a hard-coating layer.

8. The method of claim 7,
wherein the hard-coating layer includes acrylic resin.

9. The method of claim 1,
wherein the flexible substrate comprises:
an organic layer;
an under-coating layer formed on at least one surface of the organic layer;
a barrier layer formed on the under-coating layer; and
a hard-coating layer formed on the barrier layer.

10. The method of claim 9,
wherein the organic layer is made of one material selected from the group of polyacrylate, polyethylene-ether-phthalate, polyethylene-naphthalate, polycarbonate, polyarylate, polyether-imide, polyethersulfone, and polyimides.

11. The method of claim 9,
wherein the under-coating layer and the hard-coating layer include acrylic resin.

12. The method of claim 9,
wherein the barrier layer includes SiO₂ or Al₂O₃.

13. The method of claim 1,
wherein the supporter includes glass.

14. The method of claim 1,
wherein the thin film pattern includes an inorganic emitting layer.

15. The method of claim 1,
wherein the thin film pattern includes an amorphous silicon thin film transistor.

16. The method of claim 1,
wherein the thin film pattern includes an organic thin film transistor.

17. The method of claim 1,
further comprising removing the supporter from the flexible substrate.

18. The method of claim 17,
wherein the supporter is removed from the flexible substrate before the flexible substrate is divided into display device units.

19. The method of claim 17,
wherein the supporter is removed from the flexible substrate after the flexible substrate is divided into display device units.

20. The method of claim 17,
wherein the supporter is removed from the flexible substrate by temperature control, applying solvents, or irradiating with ultraviolet rays.
